(19) United States
(12) Patent Application Publication
(10) Pub. No.: US 2023/0253269 A1
(43) Pub. Date: Aug. 10, 2023

(54) SEMICONDUCTOR DEVICE AND METHOD FOR MANUFACTURING THE SAME

(71) Applicant: SONY SEMICONDUCTOR SOLUTIONS CORPORATION, KANAGAWA (JP)

(72) Inventor: YUTAKA OOTAKI

(21) Appl. No.: 18/005,010

(22) PCT Filed: May 26, 2021
(86) PCT No.: PCT/JP2021/020006

§ 371 Date: Jan. 10, 2023

(30) Foreign Application Priority Data
Jul. 20, 2020 (JP) 2020-123408

(51) Int. Cl. H01L 21/66; H01L 23/00

(52) U.S. Cl. CPC H01L 22/32; H01L 24/03; H01L 24/06; H01L 2224/0347; H01L 2224/06133

(57) ABSTRACT

To facilitate connection with an external wiring when an electrode pad is located at a deep position from a surface of a semiconductor device. The electrode pad is formed at a predetermined depth from the surface of the substrate. A conductive portion is formed in a region from the electrode pad to the surface of the substrate. The conductive portion has a state in which it can be electrically connected to the wiring on the surface of the substrate. The conductive portion includes a wiring region for electrical connection with a wiring at a position directly above the electrode pad on the surface of the substrate or at a position different from the position directly above the electrode pad. The conductive portion can be formed by repeating a procedure of applying a conductive paste to a region from the electrode pad to the surface of the substrate and a procedure of curing the applied conductive paste.

### TECHNICAL FIELD

The present technology relates to a semiconductor device. More particularly, the present invention relates to a semiconductor device in which electrode pads are formed at a deep position from the surface of a substrate, and a method for manufacturing the same.

### BACKGROUND ART

In a semiconductor device, an electrode pad for connection with an external wiring is sometimes provided at a location deeply recessed from the surface of the semiconductor device. For example, a semiconductor device has been proposed in which an electrode pad is exposed and a bonding wire is connected to the electrode pad for connection to an external wiring of a mounting substrate (see, for example, PTL 1).

### CITATION LIST

### Patent Literature

[PTL 1] JP 2014-082514A

### SUMMARY

### Technical Problem

When the electrode pads are located at a deep position as in the conventional technology described above, the height of wire bonding balls using gold wires and the height of bumps must be increased. In addition, when ultrasonic pressure bonding is performed, ultrasonic waves are less likely to reach the bonding surface (for example, the Au-Al interface), resulting in poor bonding. Moreover, even if the shear strength is measured to measure the strength of the joined wire bond, only a part of the upper part of the gold ball can be removed, making it difficult to perform an appropriate strength measurement. In particular, when applied to an imaging device, if the aperture of the electrode is widened for shear strength measurement, incident light is reflected by the electrode, causing problems in pixel characteristics and increasing the size of the imaging device. Therefore, there is a problem that it is difficult to reduce the size of the device.

The present technology has been made in view of such circumstances, and an object of the present technology is to facilitate connection with an external wiring when electrode pads are located at a deep position from the surface of a semiconductor device.

### Solution to Problem

The present technology has been made to solve the above-described problems, and a first aspect thereof is a semiconductor device including: an electrode pad formed at a predetermined depth from a surface of a substrate; and a conductive portion formed in a region from the electrode pad to the surface of the substrate and having a state in which it can be electrically connected to a wiring on the surface of the substrate. As a result, the conductive portion formed on the electrode pad brings about an effect of electrically connecting to the wiring on the surface of the substrate.

Moreover, in this first aspect, the predetermined depth may be a depth of 1 micrometer or more. More specifically, the depth may be on the order of 10 micrometers.

Moreover, in this first aspect, the conductive portion may include a wiring region for electrical connection with the wiring at a position directly above the electrode pad on the surface of the substrate. In this case, the wiring region may have an area larger than an area of the electrode pad. Further, the conductive portion may further include a probe region for contacting a probe at a position different from the position directly above the electrode pad on the surface of the substrate.

Further, in this first aspect, the conductive portion may include a wiring region for electrical connection with the wiring at a position different from the position directly above the electrode pad on the surface of the substrate. In this case, the wiring region may have an area larger than an area of the electrode pad. Moreover, the conductive portion may further include a probe region for contacting a probe at a position directly above the electrode pad on the surface of the substrate.

Moreover, in this first side surface, a plurality of sets of the electrode pads and the conductive portions may be arranged in series along the edge of the substrate. Moreover, a plurality of sets of the electrode pads and the conductive portions may be arranged in a zigzag pattern along the edge of the substrate.

Further, in the first aspect, the substrate may be a stacked substrate in which a plurality of substrates are stacked, the electrode pads may be formed on a substrate other than an outermost substrate of the stacked substrate, and the conductive portion may be embedded in a region up to the surface of the stacked substrate. For example, it may be applied to an imaging device having a stacked structure.

A second aspect of the present technology is a method for manufacturing a semiconductor device, including: a procedure of forming an electrode pad at a predetermined depth from a surface of the substrate; a procedure of applying a conductive paste in a region from the electrode pads to the surface of the substrate; and curing the applied conductive paste, wherein the procedures of applying and curing the conductive paste are repeated until the conductive paste becomes electrically connectable to a wiring on the surface of the substrate. As a result, the conductive portion formed by repeating the application and curing of the conductive paste brings about an effect of electrically connecting to the wiring on the surface of the substrate.

Moreover, in this second aspect, the procedure of applying the conductive paste may include a procedure of discharging the conductive paste from a position directly above the electrode pad.

In the second aspect, the procedure of applying the conductive paste may include: a procedure of producing a mask having openings at positions directly above the electrode pad; and a procedure of applying the conductive paste over the mask.

### BRIEF DESCRIPTION OF DRAWINGS

FIG. 1 is a cross-sectional view showing a first structural example of a semiconductor device according to an embodiment of the present technology.

FIG. 2 is a top view showing a first arrangement example of a conductive portion 150 of the first structural example of the semiconductor device according to an embodiment of the present technology.

FIG. 3 is a top view showing a second arrangement example of the conductive portion 150 of the first structural example of the semiconductor device according to the embodiment of the present technology.

FIG. 4 is a cross-sectional view showing a second structural example of the semiconductor device according to an embodiment of the present technology.

FIG. 5 is a top view showing a first arrangement example of conductive portions 150 of a second structural example of a semiconductor device according to an embodiment of the present technology.

FIG. 6 is a top view showing a second arrangement example of the conductive portion 150 of the second structural example of the semiconductor device according to the embodiment of the present technology.

FIG. 7 is a cross-sectional view showing a third structural example of the semiconductor device according to an embodiment of the present technology.

FIG. 8 is a top view showing a first arrangement example of the conductive portion 150 of the third structural example of the semiconductor device according to the embodiment of the present technology.

FIG. 9 is a top view showing a second arrangement example of the conductive portion 150 of the third structural example of the semiconductor device according to the embodiment of the present technology.

FIG. 10 is a diagram showing a mode example of applying a conductive paste 850 to a wafer 810 in a first method for manufacturing the semiconductor device according to the embodiment of the present technology.

FIG. 11 is a cross-sectional view showing a mode example of applying the conductive paste 850 in the first method for manufacturing the semiconductor device according to the embodiment of the present technology.

FIG. 12 is a flowchart showing a processing procedure example of a first method for manufacturing a semiconductor device according to an embodiment of the present technology.

FIG. 13 is a diagram showing a mode example of applying a conductive paste 850 to a wafer 810 in a second method for manufacturing the semiconductor device according to the embodiment of the present technology.

FIG. 14 is a flowchart showing a processing procedure example of the second method for manufacturing the semiconductor device according to the embodiment of the present technology.

### DESCRIPTION OF EMBODIMENTS

Modes for carrying out the present technique (hereinafter also referred to as “embodiments”) will be described below. The description will be given in the following order.
1. Structure of semiconductor device
2. Method for manufacturing semiconductor device

### 1. Structure of Semiconductor Device

### [First Structural Example]

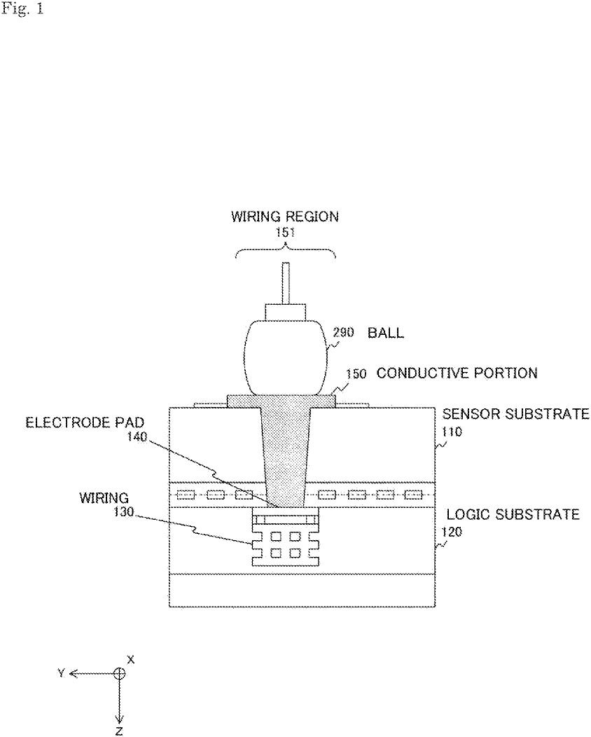

FIG. 1 is a cross-sectional view showing a first structural example of a semiconductor device according to an embodiment of the present technology.

A first structural example of the semiconductor device in the present embodiment includes a stacked substrate in which a sensor substrate 110 is stacked on a logic substrate 120. The logic substrate 120 includes a wiring 130 and electrode pads 140 connected to the wiring 130. That is, the electrode pads 140 are formed at a depth extending through the sensor substrate 110 from the surface of the sensor substrate 110.

Here, the depth at which the electrode pads 140 are formed is assumed to be, for example, 1 micrometer or more, more specifically about 10 micrometers.

A conductive portion 150 is formed in a region from the electrode pad 140 to the surface of the sensor substrate 110. As will be described later, the conductive portion 150 is formed by repeating a procedure of applying a conductive paste in a region from the electrode pad 140 to the surface of the sensor substrate 110 and a procedure of curing the applied conductive paste.

In this first structural example, the conductive portion 150 includes a wiring region 151 for electrical connection with a wiring, at a position directly above the electrode pads 140 on the surface of the sensor substrate 110. This wiring region 151 has a state in which it can be electrically connected to a wire bonding ball 290. Further, this wiring region 151 has a larger area than the electrode pad 140.

The ball 290 is a spherical member formed at the tip of the wiring when the wiring is wire-bonded, and is made of gold (Au), for example. Here, the ball 290 is electrically connected in the wiring region of the conductive portion 150.

In this first structural example, by providing the conductive portion 150, the electrical connection position of the ball 290 at the time of wire bonding can be lifted from the electrode pad 140 to the surface of the sensor substrate 110.

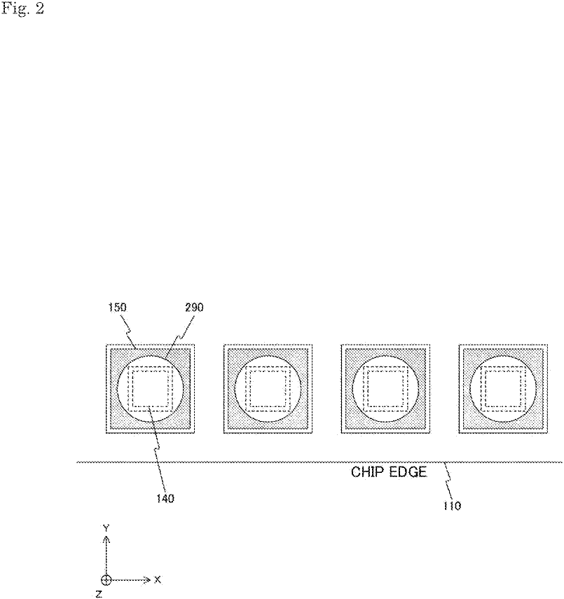

FIG. 2 is a top view showing a first arrangement example of the conductive portion 150 of the first structural example of the semiconductor device according to the embodiment of the present technology.

This first arrangement example is an example in which the conductive portions 150 are arranged in series along the chip edge (X direction) of the sensor substrate 110. Each electrode pad 140 is dug in the depth direction (Z direction), and the conductive portion 150 is exposed on the surface of the sensor substrate 110. The ball 290 is electrically connected on the conductive portion 150.

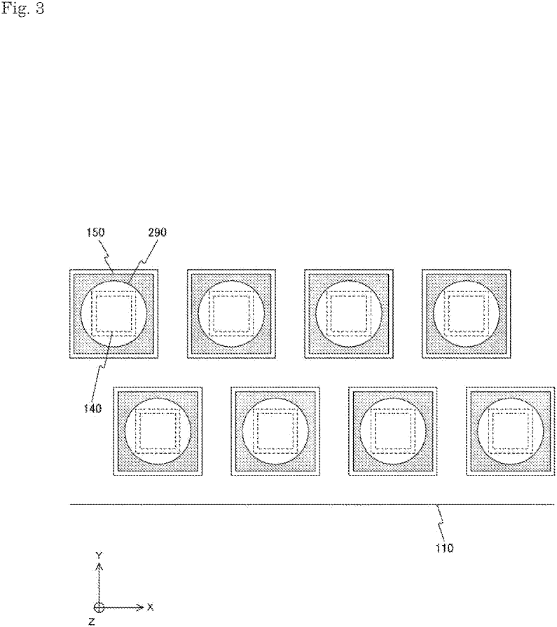

FIG. 3 is a top view showing a second arrangement example of the conductive portion 150 of the first structural example of the semiconductor device according to the embodiment of the present technology.

This second arrangement example is an example in which the conductive portions 150 are arranged in a zigzag pattern along the chip edge (X direction) of the sensor substrate 110. In this way, it is possible to improve the area efficiency when arranging the conductive portions 150 on the sensor substrate 110 and to reduce the size of the semiconductor device.

### [Second Structural Example]

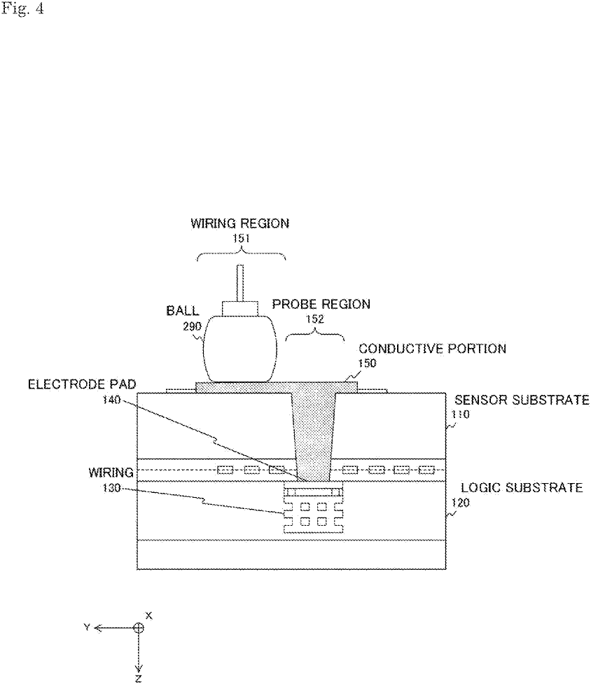

FIG. 4 is a cross-sectional view showing a second structural example of the semiconductor device according to the embodiment of the present technology.

The second structural example of the semiconductor device in the present embodiment includes a stacked substrate in which the sensor substrate 110 is stacked on the logic substrate 120, as in the first structural example described above. The logic substrate 120 includes a wiring 130 and electrode pads 140 connected to the wiring 130. That is, the electrode pads 140 are formed at a depth extending through the sensor substrate 110 from the surface of the sensor substrate 110. A conductive portion 150 is formed in a region from the electrode pad 140 to the surface of the sensor substrate 110.

In this second structural example, the conductive portion 150 has a probe region 152 for contacting a probe of a testing device or the like at a position directly above the electrode pad 140 on the surface of the sensor substrate 110. In addition, the conductive portion 150 includes a wiring region 151 for electrical connection with a wiring at a position on the surface of the sensor substrate 110 that is different from the position directly above the electrode pad 140. Further, this wiring region 151 has a larger area than the electrode pad 140.

In this second structural example, by providing the conductive portion 150, the electrical connection position of wire bonding can be lifted from the electrode pad 140 to the wiring region 151 on the surface of the sensor substrate 110, and the probe region 152 for contacting the probe can be provided.

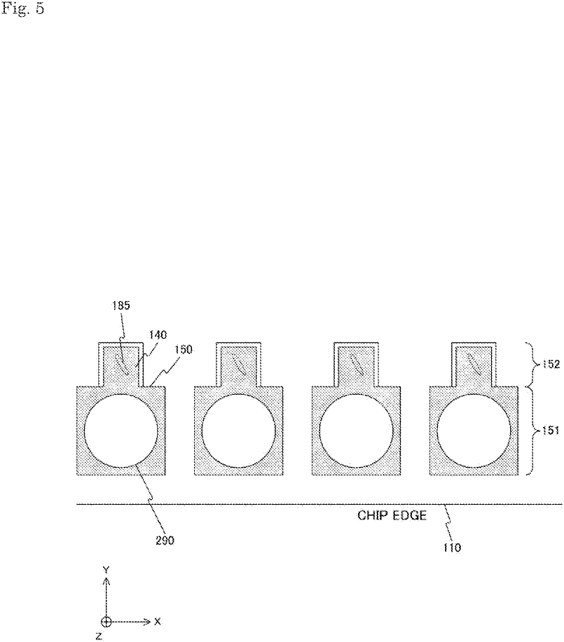

FIG. 5 is a top view showing a first arrangement example of the conductive portion 150 of the second structural example of the semiconductor device according to the embodiment of the present technology.

This first arrangement example is an example in which the conductive portions 150 are arranged in series along the chip edge (X direction) of the sensor substrate 110. Each electrode pad 140 is dug in the depth direction (Z direction), and the conductive portion 150 is exposed on the surface of the sensor substrate 110. The ball 290 is electrically connected to the wiring region 151 of the conductive portion 150. A region for contacting a probe is provided in the probe region 152 of the conductive portion 150.

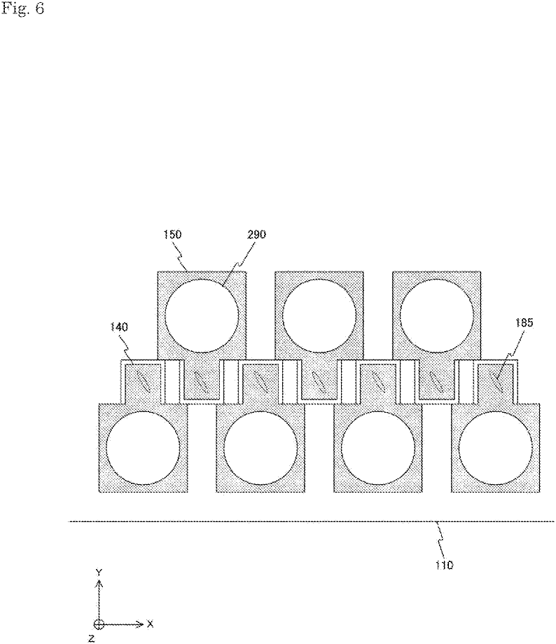

FIG. 6 is a top view showing a second arrangement example of the conductive portion 150 of the second structural example of the semiconductor device according to the embodiment of the present technology.

This second arrangement example is an example in which the conductive portions 150 are arranged in a zigzag pattern along the chip edge (X direction) of the sensor substrate 110. In this way, it is possible to improve the area efficiency when arranging the conductive portions 150 on the sensor substrate 110 and to reduce the size of the semiconductor device.

### [Third Structural Example]

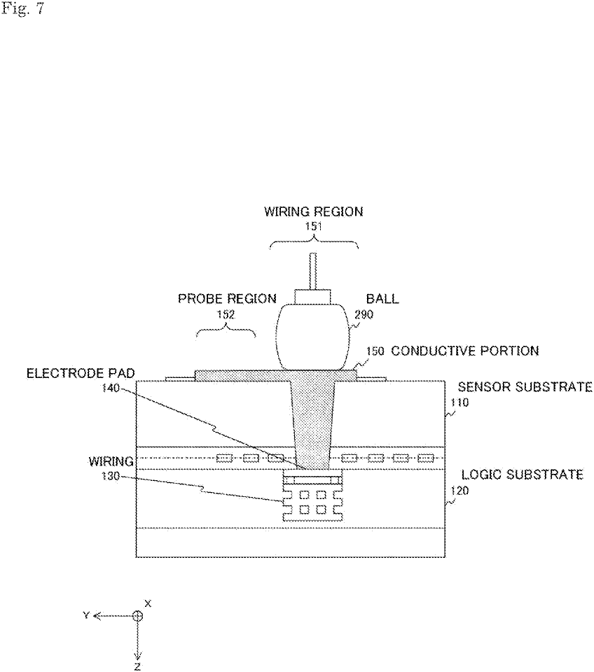

FIG. 7 is a cross-sectional view showing a third structural example of the semiconductor device according to the embodiment of the present technology.

The third structural example of the semiconductor device according to the present embodiment includes a stacked substrate in which the sensor substrate 110 is stacked on the logic substrate 120 in the same manner as the first structural example described above. The logic substrate 120 includes a wiring 130 and electrode pads 140 connected to the wiring 130. That is, the electrode pads 140 are formed at a depth extending through the sensor substrate 110 from the surface of the sensor substrate 110. A conductive portion 150 is formed in a region from the electrode pad 140 to the surface of the sensor substrate 110.

In this third structural example, the conductive portion 150 includes a wiring region 151 for electrical connection with a wiring, at a position directly above the electrode pads 140 on the surface of the sensor substrate 110. This wiring region 151 has an area larger than an area of the electrode pad 140. In addition, the conductive portion 150 includes a probe region 152 for contacting a probe of a testing device or the like at a position on the surface of the sensor substrate 110 that is different from the position directly above the electrode pad 140. That is, a structure is obtained in which the wiring region 151 and the probe region 152 are switched in position as compared with the second structural example described above.

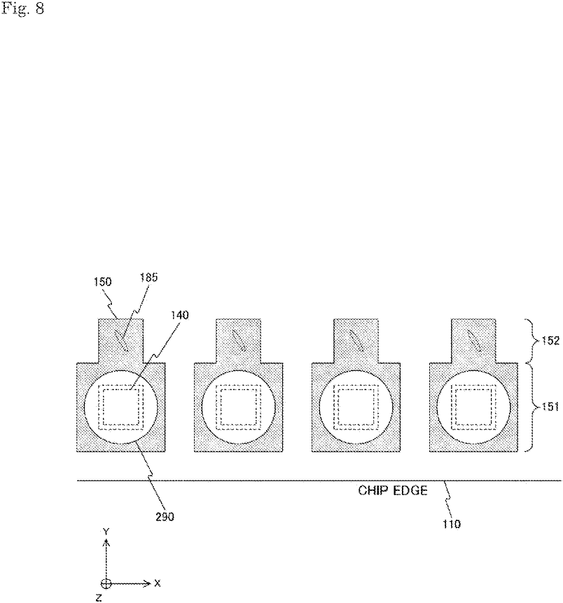

FIG. 8 is a top view showing a first arrangement example of the conductive portion 150 of the third structural example of the semiconductor device according to the embodiment of the present technology.

This first arrangement example is an example in which the conductive portions 150 are arranged in series along the chip edge (X direction) of the sensor substrate 110. Each electrode pad 140 is dug in the depth direction (Z direction), and the conductive portion 150 is exposed on the surface of the sensor substrate 110. The ball 290 is electrically connected to the wiring region 151 of the conductive portion 150. A region for contacting a probe is provided in the probe region 152 of the conductive portion 150.

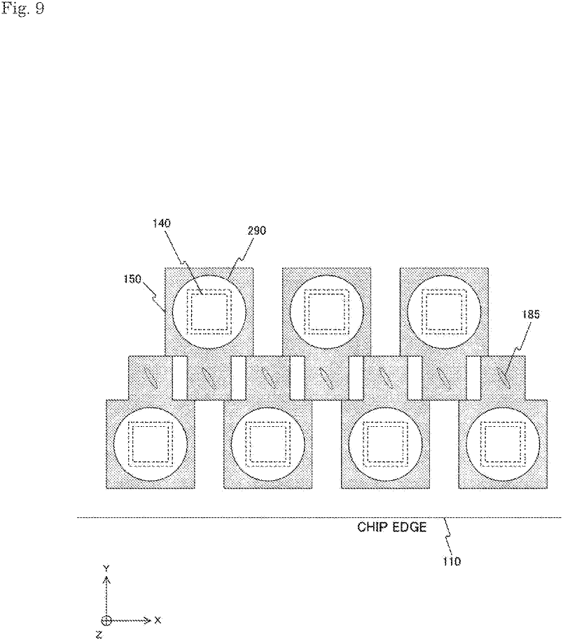

FIG. 9 is a top view showing a second arrangement example of the conductive portion 150 of the third structural example of the semiconductor device according to the embodiment of the present technology.

This second arrangement example is an example in which the conductive portions 150 are arranged in a zigzag pattern along the chip edge (X direction) of the sensor substrate 110. In this way, it is possible to improve the area efficiency when arranging the conductive portions 150 on the sensor substrate 110 and to reduce the size of the semiconductor device.

### 2. Method for Manufacturing Semiconductor Device

The first to third structural examples of the semiconductor device in the above-described embodiments can be manufactured by the manufacturing method illustrated below. A first manufacturing method example is an example in which a conductive paste is applied by discharging the conductive paste from a position directly above the electrode pad. A second manufacturing method example is an example in which a conductive paste is applied from above a mask having openings directly above the electrode pad.

### [First Manufacturing Method Example]

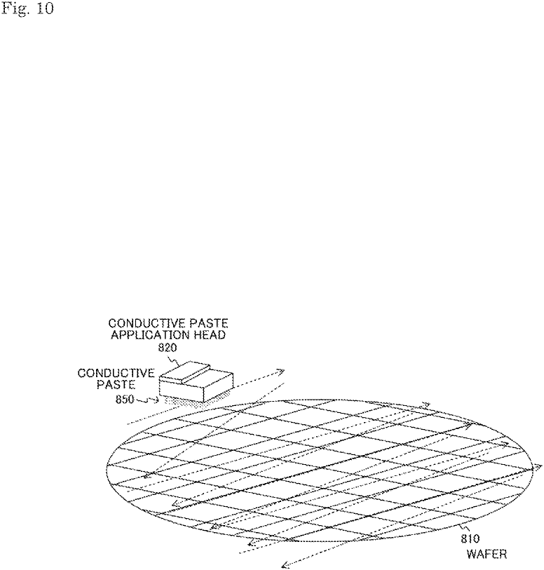

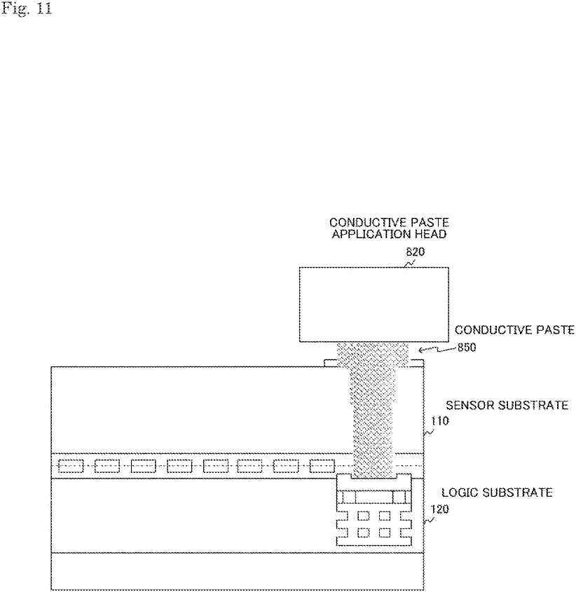

FIG. 10 is a diagram showing a mode example of applying a conductive paste 850 to a wafer 810 in the first method for manufacturing the semiconductor device according to the embodiment of the present technology. FIG. 11 is a cross-sectional view showing a mode example of applying the conductive paste 850 in the first manufacturing method of the semiconductor device according to the embodiment of the present technology.

This first manufacturing method example is a method of scanning the surface of the wafer 810 with a conductive paste application head 820, discharging and applying the conductive paste 850 only to the positions corresponding to the electrode pads 140, and stacking the same.

The conductive paste 850 is a paste-like member having conductivity, and is manufactured, for example, by mixing metal powder such as silver (Ag) or copper (Cu) with resin. The conductive paste 850 may be, for example, a conductive nanopaste.

Examples of methods for discharging and applying the conductive paste 850 include an inkjet method, a dispensing method, and an aerosol jet method.

As a method of curing the applied conductive paste 850, for example, a method of irradiating with light or heat, a laser cure using a laser, or the like is assumed.

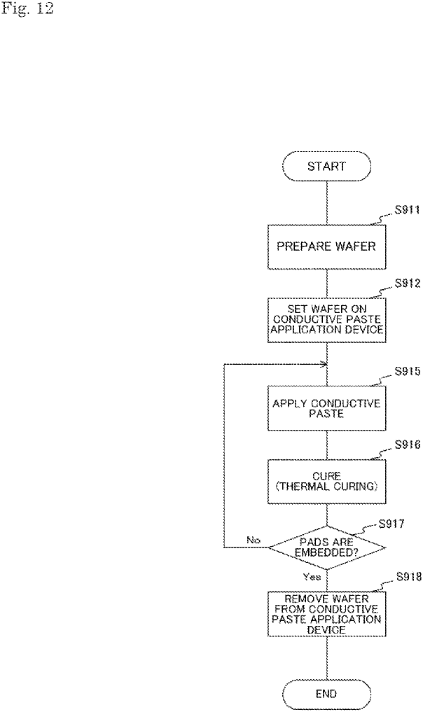

FIG. 12 is a flowchart showing a processing procedure example of the first method for manufacturing the semiconductor device according to the embodiment of the present technology.

First, a target wafer 810 is prepared (step S911), and the wafer 810 is set on a conductive paste application device (step S912).

Next, using the conductive paste application head 820 of the conductive paste application device, the conductive paste 850 is applied by discharging (dispensing) the conductive paste 850 onto the surface of the electrode pad 140 (step S915). Then, the applied conductive paste 850 is cured by light or heat irradiation or laser curing (step S916).

The procedure of applying the conductive paste 850 (step S915) and the procedure of curing (step S916) are repeated until the conductive paste 850 is stacked on the surface of the sensor substrate 110 (step S917: No).

When the series of processes is completed (step S917: Yes), the wafer 810 is removed from the conductive paste application device (step S918).

### [Second Manufacturing Method Example]

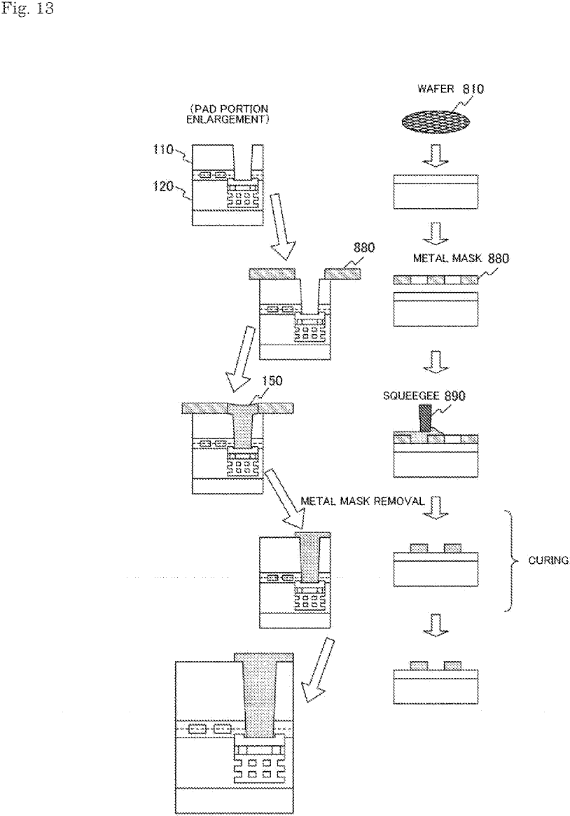

FIG. 13 is a diagram showing a mode example of applying the conductive paste 850 to the wafer 810 in the second method for manufacturing the semiconductor device according to the embodiment of the present technology.

In this second manufacturing method example, a metal mask 880 having openings corresponding to the electrode pads 140 is attached to the surface of the wafer 810, and the conductive paste 850 is applied using a squeegee 890 to stack layers.

The squeegee 890 is a spatula-like tool. The conductive paste 850 is applied through the openings of the metal mask 880 by pressing the squeegee 890 with the conductive paste 850 piled up on the metal mask 880.

The method of curing the applied conductive paste 850 is the same as in the first example of the manufacturing method described above, and for example, a method of irradiating with light or heat, a laser cure using a laser, or the like is assumed.

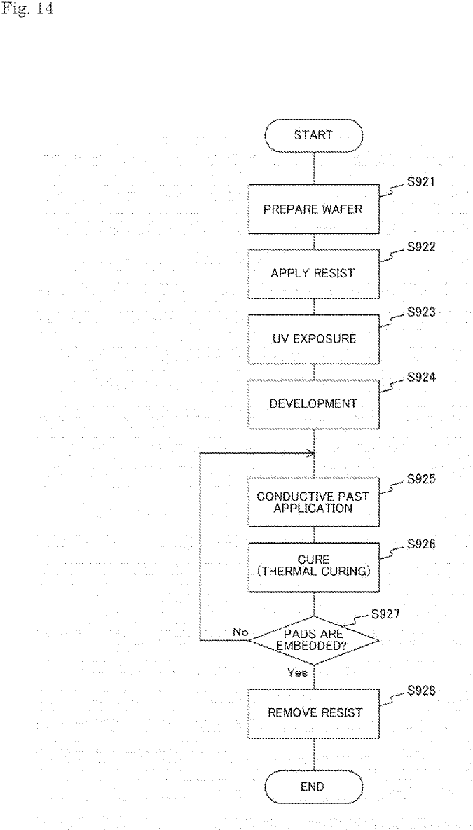

FIG. 14 is a flowchart showing a processing procedure example of the second method for manufacturing the semiconductor device according to the embodiment of the present technology.

First, a target wafer 810 is prepared (step S921), a resist is applied to the wafer 810 (step S922), UV-exposed (step S923), and developed (step S924) to produce a metal mask 880.

Next, using the squeegee 890, the conductive paste 850 is applied through the openings of the metal mask 880 (step S925). Then, the applied conductive paste 850 is cured by light or heat irradiation or laser curing (step S926).

The procedure of applying the conductive paste 850 (step S925) and the procedure of curing (step S926) are repeated until the conductive paste 850 is stacked on the surface of the sensor substrate 110 (step S927: No).

When the series of processes is completed (step S927: Yes), the resist is removed (step S928).

As described above, according to the embodiment of the present technology, by repeating the application and curing of the conductive paste 850 to form the conductive portion 150, the electrical connection position of the ball 290 at the time of wire bonding can be lifted from the electrode pad 140 to the surface of the sensor substrate 110.

When an electrode located at a deep position from the surface of a semiconductor device is to be pulled up to the surface using the semiconductor manufacturing process, optimization of the circuit design that forms the semiconductor device, wiring for pulling up the electrode, and construction of the via formation are required. Thus, it is expected that there will be an increase in the number of processes, resulting in high added value. On the other hand, in the present embodiment, it is possible to pull up the electrode at a deep position at low cost by combining existing assembly processes without using the semiconductor manufacturing process. In addition, the size of the semiconductor device can be reduced and the manufacturing process can be simplified by reducing the size of the electrode itself, applying a conductive paste discharged to bury the electrode, or stacking the conductive past by a squeegee method, and drawing the electrode out to the surface of the semiconductor device to form a new electrode. Furthermore, by drawing the electrodes out to the surface of the semiconductor device, it is possible to bond the electrodes with the optimum wire bonding shape using wire bonding technology represented by gold wire, and to check whether the bonding is proper on the surface of the semiconductor device.

It should be noted that the above-described embodiments show examples for embodying the present technique, and matters in the embodiments and matters specifying the invention in the claims have a corresponding relationship with each other. Similarly, the matters specifying the invention in the claims and the matters in the embodiments of the present technology having the same name have a corresponding relationship with each other. However, the present technology is not limited to the embodiments and can be embodied by applying various modifications to the embodiments without departing from the gist thereof.

The effects described in the present specification are merely examples and are not intended as limiting, and other effects may be obtained.

The present technology can also have the following configurations.

A semiconductor device including:
an electrode pad formed at a predetermined depth from a surface of a substrate; and
a conductive portion formed in a region from the electrode pad to the surface of the substrate and having a state in which it can be electrically connected to a wiring on the surface of the substrate.

The semiconductor device according to (1), wherein the predetermined depth is a depth of 1 micrometer or more.

The semiconductor device according to (1) or (2), wherein the conductive portion has a wiring region for electrical connection with the wiring at a position directly above the electrode pad on the surface of the substrate.

The semiconductor device according to (3), wherein the wiring region has a larger area than an area of the electrode pad.

The semiconductor device according to (3) or (4), wherein the conductive portion further has a probe region for contacting a probe at a position different from the position directly above the electrode pad on the surface of the substrate.

The semiconductor device according to (1) or (2), wherein the conductive portion has a wiring region for electrical connection with the wiring at a position different from the position directly above the electrode pad on the surface of the substrate.

The semiconductor device according to (6), wherein the conductive portion further has a probe region for contacting a probe at a position directly above the electrode pad on the surface of the substrate.

The semiconductor device according to any one of (1) to (7), wherein a plurality of sets of the electrode pads and the conductive portions are arranged in series along an edge of the substrate.

The semiconductor device according to any one of (1) to (7), wherein a plurality of sets of the electrode pads and the conductive portions are arranged in a zigzag pattern along an edge of the substrate.

The semiconductor device according to any one of (1) to (9), wherein
the substrate is a stacked substrate in which a plurality of substrates are stacked,
the electrode pads are formed on a substrate other than an outermost substrate of
the stacked substrate, and
the conductive portion is embedded in a region up to the surface of the stacked substrate.

A method for manufacturing a semiconductor device, including:
a procedure of forming an electrode pad at a predetermined depth from a surface of the substrate;
a procedure of applying a conductive paste in a region from the electrode pads to the surface of the substrate; and
curing the applied conductive paste, wherein
the procedures of applying and curing the conductive paste are repeated until the conductive paste becomes electrically connectable to a wiring on the surface of the substrate.

The method for manufacturing the semiconductor device according to (11), wherein
the procedure of applying the conductive paste includes a procedure of discharging
the conductive paste from a position directly above the electrode pad.

The method for manufacturing the semiconductor device according to (11), wherein
the procedure of applying the conductive paste includes:
a procedure of producing a mask having openings at positions directly above the electrode pad; and
a procedure of applying the conductive paste over the mask.

Reference Signs List

| | |
|---|---|
| 110 | Sensor substrate |
| 120 | Logic substrate |
| 130 | Wiring |
| 140 | Electrode pad |
| 150 | Conductive portion |
| 151 | Wiring region |
| 152 | Probe region |
| 290 | Ball |
| 810 | Wafer |
| 820 | Conductive paste application head |
| 850 | Conductive paste |
| 880 | Metal mask |
| 890 | Squeegee |

1. A semiconductor device comprising:
an electrode pad formed at a predetermined depth from a surface of a substrate; and a conductive portion formed in a region from the electrode pad to the surface of the substrate and having a state in which it can be electrically connected to a wiring on the surface of the substrate.

2. The semiconductor device according to claim 1, wherein
the predetermined depth is a depth of 1 micrometer or more.

3. The semiconductor device according to claim 1, wherein
the conductive portion has a wiring region for electrical connection with the wiring at a position directly above the electrode pad on the surface of the substrate.

4. The semiconductor device according to claim 3, wherein
the wiring region has a larger area than an area of the electrode pad.

5. The semiconductor device according to claim 3, wherein
the conductive portion further has a probe region for contacting a probe at a position different from the position directly above the electrode pad on the surface of the substrate.

6. The semiconductor device according to claim 1, wherein
the conductive portion has a wiring region for electrical connection with the wiring at a position different from the position directly above the electrode pad on the surface of the substrate.

7. The semiconductor device according to claim 6, wherein
the conductive portion further has a probe region for contacting a probe at a position directly above the electrode pad on the surface of the substrate.

8. The semiconductor device according to claim 1, wherein
a plurality of sets of the electrode pads and the conductive portions are arranged in series along an edge of the substrate.

9. The semiconductor device according to claim 1, wherein
a plurality of sets of the electrode pads and the conductive portions are arranged in a zigzag pattern along an edge of the substrate.

10. The semiconductor device according to claim 1, wherein
the substrate is a stacked substrate in which a plurality of substrates are stacked, the electrode pads are formed on a substrate other than an outermost substrate of the stacked substrate, and
the conductive portion is embedded in a region up to the surface of the stacked substrate.

11. A method for manufacturing a semiconductor device, comprising:
a procedure of forming an electrode pad at a predetermined depth from a surface of the substrate;
a procedure of applying a conductive paste in a region from the electrode pads to the surface of the substrate; and
curing the applied conductive paste, wherein
the procedures of applying and curing the conductive paste are repeated until the conductive paste becomes electrically connectable to a wiring on the surface of the substrate.

12. The method for manufacturing the semiconductor device according to claim 11, wherein
the procedure of applying the conductive paste includes a procedure of discharging the conductive paste from a position directly above the electrode pad.

13. The method for manufacturing the semiconductor device according to claim 11, wherein
the procedure of applying the conductive paste includes:
a procedure of producing a mask having openings at positions directly above the electrode pad; and
a procedure of applying the conductive paste over the mask.
